(19) United States
(12) Patent Application Publication
(10) Pub. No.: US 2022/0149125 A1
(43) Pub. Date: May 12, 2022

(54) DISPLAY DEVICE AND METHOD OF MANUFACTURING THE SAME

(71) Applicant: Samsung Display Co., Ltd., Yongin-si (KR)

(72) Inventor: Kyongtae YU, Yongin-si (KR)

(73) Assignee: Samsung Display Co., Ltd., Yongin-si (KR)

(21) Appl. No.: 17/324,666

(22) Filed: May 19, 2021

(30) Foreign Application Priority Data
Nov. 10, 2020 (KR) 10-2020-0149589

(51) Int. Cl. H01L 27/32; H01L 51/56

(52) U.S. Cl. CPC H01L 27/3246; H01L 2227/323; H01L 51/56

(57) ABSTRACT

A display device includes a lower electrode disposed on a substrate; a pixel-defining layer overlapping an edge of the lower electrode, the pixel-defining layer comprising an opening that exposes a central portion of the lower electrode; an emission layer overlapping the opening and arranged on the lower electrode; an upper electrode disposed on the emission layer; and at least one repellent pattern disposed on an upper surface of the pixel-defining layer and a portion of a side surface of the pixel-defining layer, wherein the side surface of the pixel-defining layer defines the opening.

### CROSS-REFERENCE TO RELATED APPLICATION (S)

This application claims priority to and the benefit of Korean Patent Application No. 10-2020-0149589 under 35 U.S.C. § 119, filed on Nov. 10, 2020, in the Korean Intellectual Property Office (KIPO), the entire contents of which are incorporated herein by reference.

### BACKGROUND

### 1. Technical Field

One or more embodiments relate to a display device and a method of manufacturing the display device.

### 2. Description of Related Art

As the information society develops, demand for display devices for displaying images has increased in various forms. The field of display devices has rapidly changed to flat panel display devices (FPDs) that are thinner, lighter, and larger, to replace bulky cathode ray tubes (CRTs). FPDs include liquid crystal display devices (LCDs), plasma display panels (PDPs), organic light-emitting display devices (OLEDs), electrophoretic display devices (EPDs), and the like.

Among the display devices, the organic light-emitting display device may include an organic light-emitting diode having an upper electrode, an emission layer, and a lower electrode, as a display element. In case that a voltage is applied to the upper electrode and the lower electrode of the organic light-emitting diode, visible light may be emitted from the emission layer. The emission layer of the organic light-emitting diode may be formed by discharging ink including a light-emitting material onto the lower electrode.

### SUMMARY

One or more embodiments include a display device in which a shape of an emission layer thereof is adjusted, and a method of manufacturing the display device.

Additional aspects will be set forth in part in the description which follows and, in part, will be apparent from the description, or may be learned by practice of the embodiments of the disclosure.

According to an embodiment, a display device may include a lower electrode disposed on a substrate, a pixel-defining layer overlapping an edge of the lower electrode, the pixel-defining layer including an opening that exposes a central portion of the lower electrode, an emission layer overlapping the opening and arranged on the lower electrode, an upper electrode disposed on the emission layer, and at least one repellent pattern disposed on an upper surface of the pixel-defining layer and a portion of a side surface of the pixel-defining layer. The side surface of the pixel-defining layer may define the opening.

The side surface of the pixel-defining layer may include a first surface that overlaps the at least one repellent pattern, and a second surface that extends from an edge of the at least one repellent pattern to the lower electrode, and at least partially overlaps the emission layer.

The at least one repellent pattern may be spaced apart from the lower electrode.

The upper electrode may overlap the at least one repellent pattern disposed on the upper surface of the pixel-defining layer.

The lower electrode may include a first lower electrode and a second lower electrode that are spaced apart from each other, the opening may include a first opening and a second opening, the first opening exposing a central portion of the first lower electrode, and the second opening exposing a central portion of the second lower electrode, the emission layer may include a first emission layer and a second emission layer, the first emission layer being arranged on the first lower electrode, and the second emission layer being spaced apart from the first emission layer and arranged on the second lower electrode, and the at least one repellent pattern may be arranged on the upper surface of the pixel-defining layer, a portion of a first side surface of the pixel-defining layer defining the first opening, and a portion of a second side surface of the pixel-defining layer defining the second opening.

The display device may further include a lower functional layer including a first lower functional layer and a second lower functional layer, and an upper functional layer between the emission layer and the upper electrode. The first lower functional layer may be arranged between the first lower electrode and the first emission layer, the second lower functional layer may be arranged between the second lower electrode and the second emission layer and spaced apart from the first lower functional layer, and the upper functional layer may be arranged between the repellent pattern and the upper electrode on the upper surface of the pixel-defining layer.

The at least one repellent pattern may include a plurality of repellent pattern, and the plurality of repellent patterns may be spaced apart from each other with the emission layer arranged therebetween.

The at least one repellent pattern may include a fluorine-based component.

The display device may further include a spacer between the pixel-defining layer and the at least one repellent pattern.

The display device may further include a capping layer arranged on the upper electrode and overlapping the emission layer and the at least one repellent pattern.

According to another embodiment, a method of manufacturing a display device includes preparing a display substrate that includes a substrate and a lower electrode on the substrate, forming a pixel-defining layer that overlaps an edge of the lower electrode, the pixel-defining layer including an opening that exposes a central portion of the lower electrode, forming at least one repellent pattern on an upper surface of the pixel-defining layer and a portion of a side surface of the pixel-defining layer defining the opening, and forming an emission layer on the lower electrode. A side surface of the pixel-defining layer may define the opening and include a first surface and a second surface, the first surface may overlap the at least one repellent pattern, and the second surface may extend from an edge of the at least one repellent pattern to the lower electrode.

The forming of the at least one repellent pattern may include disposing, on the display substrate, a mask including a mask opening, and the mask opening may be arranged to overlap the pixel-defining layer.

The at least one repellent pattern may be spaced apart from the lower electrode.

The at least one repellent pattern may include a plurality of repellent patterns, and the plurality of repellent patterns may be spaced apart from each other.

The forming of the emission layer may include applying ink including a light-emitting material onto the lower electrode.

The method may further include forming an upper functional layer on the emission layer and the at least one repellent pattern, and forming an upper electrode on the upper functional layer.

The method may further include forming a capping layer on the upper electrode.

The method may further include forming a lower functional layer by applying ink onto the lower electrode. The forming of the emission layer may include forming the emission layer on the lower functional layer.

The method may further include forming a spacer on the pixel-defining layer.

The method may further include plasma-cleaning the lower electrode.

### BRIEF DESCRIPTION OF THE DRAWINGS

The above and other aspects, features, and advantages of embodiments of the disclosure will be more apparent from the following description taken in conjunction with the accompanying drawings, in which:

FIG. 1 is a perspective view schematically illustrating a display device according to an embodiment;

FIG. 2 is a schematic equivalent circuit diagram of a sub-pixel included in a display device according to an embodiment;

FIG. 3A is a cross-sectional view schematically illustrating a display device according to an embodiment;

FIG. 3B is a cross-sectional view schematically illustrating a display device according to another embodiment;

FIGS. 4A and 4B are cross-sectional views schematically illustrating a first sub-pixel and a second sub-pixel of a display device according to an embodiment;

FIG. 5 is a cross-sectional view schematically illustrating a Comparative Example for comparison with an embodiment of the disclosure; and

FIGS. 6A to 6F are cross-sectional views illustrating a method of manufacturing a display device according to an embodiment.

### DETAILED DESCRIPTION OF THE EMBODIMENTS

Reference will now be made in detail to embodiments, examples of which are illustrated in the accompanying drawings, wherein like reference numerals refer to like elements throughout the disclosure. In this regard, the embodiments may have different forms and configurations and should not be construed as being limited to the descriptions set forth herein. Accordingly, the embodiments are merely described below, by referring to the figures, to explain aspects of the disclosure. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or any variations thereof.

The disclosure may include various embodiments and modifications, and embodiments thereof will be illustrated in the drawings and will be described herein in detail. The effects and features of the disclosure and the accompanying methods thereof will become apparent from the following description of the embodiments, taken in conjunction with the accompanying drawings. However, the disclosure is not limited to the embodiments described below and may be embodied in various modes.

Hereinafter, the disclosure will be described in detail by explaining embodiments of the disclosure with reference to the attached drawings. Repetitive explanations are omitted.

In the embodiments below, it will be understood that although the terms “first,” “second,” and the like may be used herein to describe various elements, these elements should not be limited by these terms. These elements are only used to distinguish one component from another component.

As used herein, the singular forms “a,” “an,” and “the” are intended to include the plural forms as well, unless the context clearly indicates otherwise.

In the embodiments below, it will be understood that the terms “comprise,” “include,” “have” or variations thereof used herein specify the presence of stated features or elements, but do not preclude the presence or addition of one or more other features or elements.

It will be further understood that a layer, region, or element that is “formed on” another layer, area, or element may be directly or indirectly formed on the other layer, region, or element. That is, for example, intervening layers, regions, or elements may be present therebetween.

Sizes of elements in the drawings may be exaggerated or contracted for convenience of explanation. In other words, because sizes and thicknesses of elements in the drawings are arbitrarily illustrated for convenience of explanation, the following embodiments are not limited thereto.

When an embodiment may be implemented differently, a process order may be performed differently from the described order. For example, two consecutively described processes may be performed substantially at the same time or performed in an order opposite to the described order.

It will be understood that when a layer, region, or element is referred to as being “connected,” the layer, the region, or the element may be directly connected or may be indirectly connected with intervening layers, regions, or elements therebetween. For example, when a layer, region, or element is referred to as being “electrically connected to” or “electrically coupled to” another layer, region, or element, it may be directly or indirectly electrically connected or coupled to the other layer, region, or element. For example, intervening layers, regions, or elements may be present therebetween.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

A display device displays an image and may be a portable mobile device such as game consoles, multimedia devices, or micro PCs. For example, display devices to be described below may include liquid crystal display devices, electrophoretic display devices, organic light-emitting displays, inorganic light-emitting displays, field emission displays, surface-conduction electrode-emitter displays, quantum dot displays, plasma displays, cathode ray displays, or the like. Hereinafter, an organic light-emitting display device will be described as an example of a display device according to an embodiment, but embodiments of the disclosure may be various other types of display devices as described above.

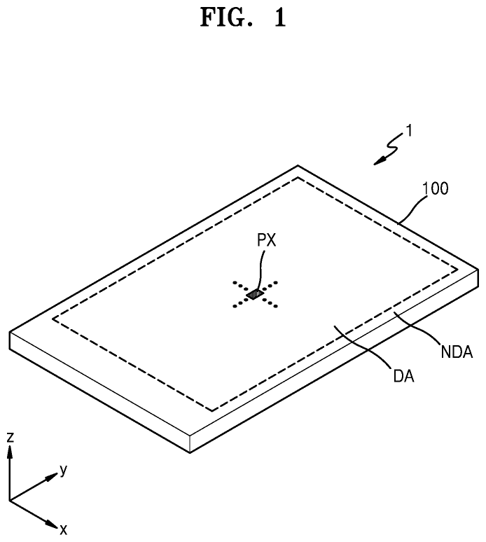

FIG. 1 is a perspective view schematically illustrating a display device 1 according to an embodiment.

Referring to FIG. 1, the display device 1 may include a display area DA and a non-display area NDA on a substrate 100.

The display area DA may display images. Subpixels PX may be arranged in the display area DA. An image may be provided by using light emitted from the subpixels PX.

The non-display area NDA may be an area that does not provide an image, and no subpixels PX are arranged in the non-display area NDA. The non-display area NDA may entirely surround the display area DA. A driver or the like for providing an electrical signal or power to the subpixels PX may be arranged in the non-display area NDA. The non-display area NDA may include a pad portion (not shown), which is an area to which an electronic element, a printed circuit board, or the like may be electrically connected.

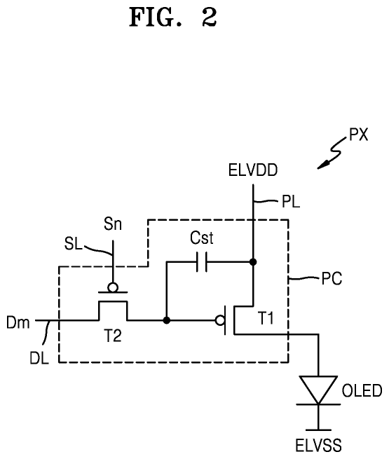

FIG. 2 is a schematic equivalent circuit diagram of a subpixel PX included in a display device according to an embodiment.

Referring to FIG. 2, the subpixel PX may include a pixel circuit PC and a display element electrically connected thereto, for example, an organic light-emitting diode OLED. The pixel circuit PC may include a driving thin-film transistor T1, a switching thin-film transistor T2, and a storage capacitor Cst. For example, each of the subpixels PX may emit, from the organic light-emitting diode OLED, one of red light, green light, and blue light or one of red light, green light, blue light, and white light.

The switching thin-film transistor T2 may be electrically connected to a scan line SL and a data line DL and may transmit a data voltage or a data signal Dm received via the data line DL to the driving thin-film transistor T1 according to a switching voltage or a switching signal Sn received via the scan line SL. The storage capacitor Cst may be electrically connected to the switching thin-film transistor T2 and a driving voltage line PL and may store a voltage difference between a voltage received from the switching thin-film transistor T2 and a first power voltage ELVDD applied to the driving voltage line PL.

The driving thin-film transistor T1 may be electrically connected to the driving voltage line PL and the storage capacitor Cst and may control a driving current flowing to the organic light-emitting diode OLED from the driving voltage line PL according to the voltage stored in the storage capacitor Cst. The organic light-emitting diode OLED may emit light having a luminance according to the driving current. An opposite electrode (e.g., a cathode) of the organic light-emitting diode OLED may be configured to receive a second power voltage ELVSS.

FIG. 2 illustrates that the pixel circuit PC includes two thin-film transistors and a storage capacitor, but in an embodiment, the number of thin-film transistors and the number of storage capacitors may be variously changed according to the design of the pixel circuit PC.

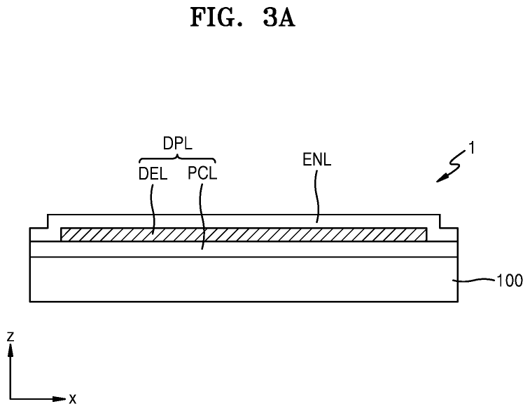

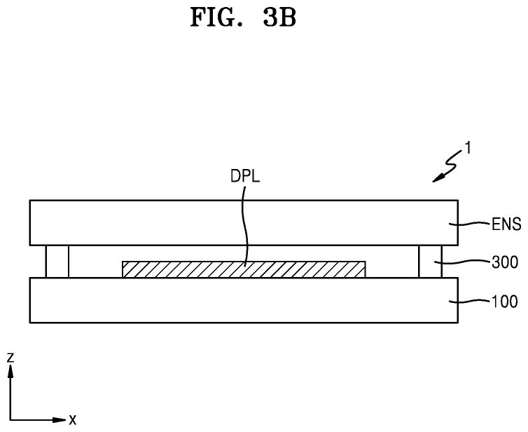

FIG. 3A is a cross-sectional view schematically illustrating a display device 1 according to an embodiment. FIG. 3B is a cross-sectional view schematically illustrating a display device 1 according to another embodiment.

Referring to FIG. 3A, a display layer DPL and an encapsulation layer ENL may be included on a substrate 100 of the display device 1. The display layer DPL may include a pixel circuit layer PCL and a display element layer DEL, the pixel circuit layer PCL may include a pixel circuit and insulating layers, and the display element layer DEL may include display elements on the pixel circuit layer PCL.

The substrate 100 may include glass or a polymer resin such as polyethersulfone, polyarylate, polyetherimide, polyethylene naphthalate, polyethylene terephthalate, polyphenylene sulfide, polyimide, polycarbonate, cellulose triacetate (TAC), cellulose acetate propionate, or the like.

A barrier layer (not shown) may be further included between the pixel circuit layer PCL and the substrate 100. The barrier layer may be a layer that prevents the penetration of foreign substances and may be a single layer or multiple layers including an inorganic material, such as silicon nitride (SiNₓ) and silicon oxide (SiO₂).

The display element layer DEL may include display elements, for example, an organic light-emitting diode. The pixel circuit layer PCL may include a pixel circuit and insulating layers, wherein the pixel circuit is electrically connected to the organic light emitting diode. The pixel circuit layer PCL may include thin-film transistors, storage capacitors, and insulating layers interposed therebetween.

The display elements may be covered or overlapped by an encapsulation member, such as the encapsulation layer ENL. The encapsulation layer ENL may include at least one inorganic encapsulation layer and at least one organic encapsulation layer, which cover or overlap the display element layer DEL. The inorganic encapsulation layer may include one or more inorganic materials from among aluminum oxide (Al₂O₃), titanium oxide (TiO₂), tantalum oxide (Ta₂O₅), zinc oxide (ZnO), SiO₂, SiNₓ, and silicon oxynitride (SiON). The organic encapsulation layer may include a polymer-based material. The polymer-based material may include acryl-based resins, epoxy-based resins, polyimide, polyethylene, or the like. In an embodiment, the organic encapsulation layer may include acrylate.

Referring to FIG. 3B, the display layer DPL and an encapsulation substrate ENS may be arranged on the substrate 100 of the display device 1. A sealing member 300 may be arranged between the substrate 100 and the encapsulation substrate ENS. The encapsulation substrate ENS may be a transparent member. Each of the substrate 100 and the encapsulation substrate ENS may be connected to the sealing member 300 so as to seal an inner space between the substrate 100 and the encapsulation substrate ENS. An absorbent, a filler, or the like may be positioned in the inner space. The sealing member 300 may be a sealant, and in an embodiment, the sealing member 300 may include a material that is cured by laser. For example, the sealing member 300 may include a frit. In an embodiment, the sealing member 300 may include an organic sealant such as urethane-based resins, epoxy-based resins, acryl-based resins, or an inorganic sealant, such as silicone. For example, the urethane-based resins may include urethane acrylate or the like. For example, the acryl-based resins may include butyl acrylate, ethyl hexyl acrylate, or the like. Moreover, the sealing member 300 may include a material that is cured by heat.

In some embodiments, the display layer DPL may be covered or overlapped by the encapsulation substrate ENS and the sealing member 300 in FIG. 3B together with the encapsulation layer ENL in FIG. 3A.

Although not shown in the drawings, a touch electrode layer may be arranged on the encapsulation layer ENL and/or the encapsulation substrate ENS, and an optical functional layer may be arranged on the touch electrode layer. The touch electrode layer may obtain coordinate information according to an external input, for example, a touch event. The optical functional layer may reduce the reflectance of light, for example external light incident from the outside onto the display device 1, and/or may improve the color purity of light emitted from the display device 1. In an embodiment, the optical functional layer may include a retarder and/or a polarizer. The retarder may be of a film type or a liquid-crystal coating type and may include a A/2 retarder and/or a A/4 retarder. The polarizer may also be of a film type or a liquid-crystal coating type. The film-type polarizer may include an elongated synthetic resin film, and the liquid-crystal-coating-type polarizer may include liquid crystals arranged with an orientation. The retarder and the polarizer may further include a protective film.

In an embodiment, the optical functional layer may include a black matrix and color filters. The color filters may be arranged by taking into account a color of light emitted from each of the subpixels PX of the display device 1. Each of the color filters may include a red, green, or blue pigment or dye. In some embodiments, each of the color filters may further include quantum dots in addition to the above-mentioned pigment or dye. As another example, some of the color filters may not include the above-mentioned pigment or dye, but may include scattering particles, such as titanium oxide (TiO₂).

In an embodiment, the optical functional layer may include a destructive interference structure. The destructive interference structure may include a first reflective layer and a second reflective layer arranged on different layers. First reflected light and second reflected light respectively reflected by the first reflective layer and the second reflective layer may destructively interfere with each other, thereby reducing the reflectance of external light.

An adhesive member may be arranged between the touch electrode layer and the optical functional layer. Any of general adhesives in the art may be used as the adhesive member. The adhesive member may be a pressure-sensitive adhesive (PSA).

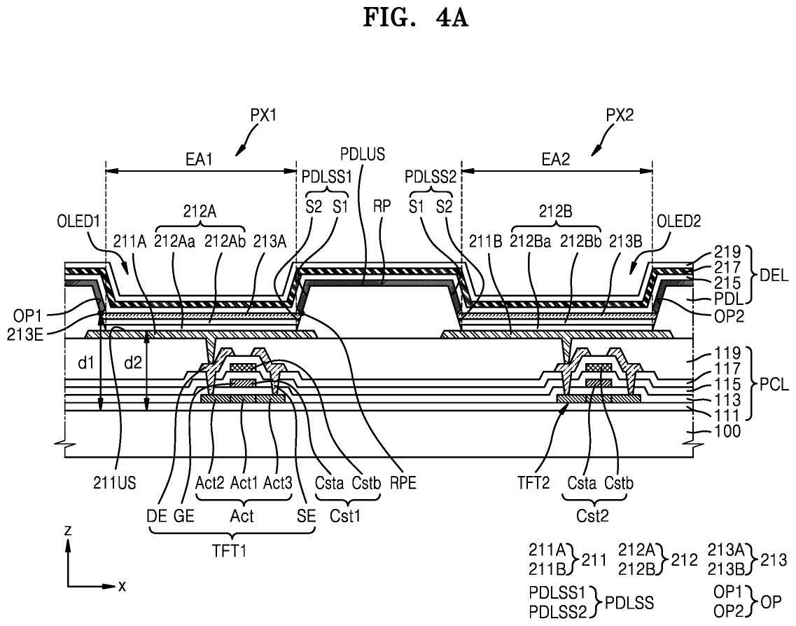

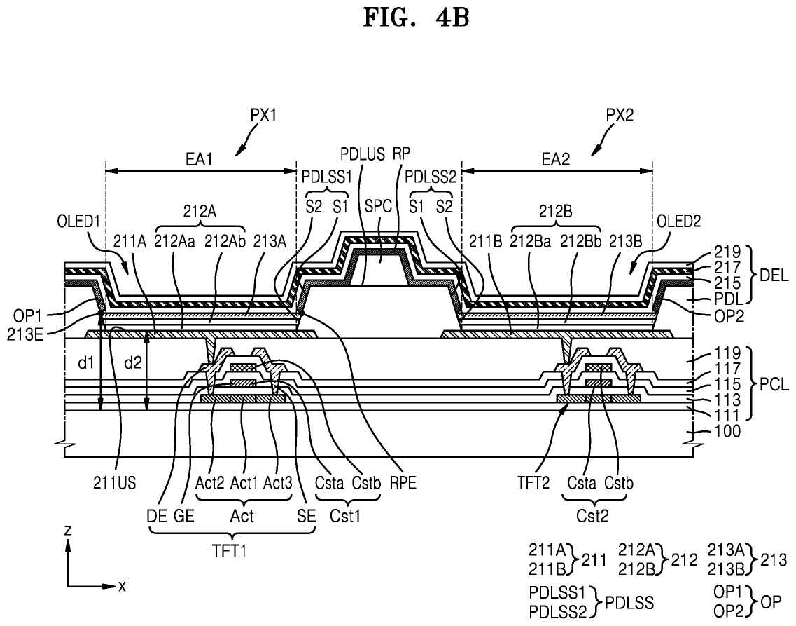

FIGS. 4A and 4B are cross-sectional views schematically illustrating a first subpixel PX1 and a second subpixel PX2 of a display device according to an embodiment. In FIGS. 4A and 4B, the same reference symbols as those of FIG. 3A denote the same members, and repetitive descriptions thereof will be omitted.

FIGS. 4A and 4B illustrate the first subpixel PX1 and the second subpixel PX2 that are adjacent to each other. A first organic light-emitting diode OLED1 of the first subpixel PX1 and a second organic light-emitting diode OLED2 of the second subpixel PX2 may be adjacent to each other.

Referring to FIGS. 4A and 4B, the display device may include a substrate 100, a pixel circuit layer PCL, and a display element layer DEL.

The pixel circuit layer PCL may be arranged on the substrate 100. The pixel circuit layer PCL may include at least one thin-film transistor, at least one storage capacitor, a buffer layer 111, a first gate insulating layer 113, a second gate insulating layer 115, an interlayer insulating layer 117, and a planarization layer 119. The at least one thin-film transistor may include a first thin-film transistor TFT1 and a second thin-film transistor TFT2. The at least one storage capacitor may include a first storage capacitor Cst1 and a second storage capacitor Cst2. Because the second thin-film transistor TFT2 is similar to the first thin-film transistor TFT1, the first thin-film transistor TFT1 will be mainly described in detail. Because the second storage capacitor Cst2 is similar to the first storage capacitor Cst1, the first storage capacitor Cst1 will be mainly described in detail.

The buffer layer 111 may be arranged on the substrate 100. The buffer layer 111 may include an inorganic insulating material such as SiNₓ, SiON, and SiO₂, and may be a single layer or multiple layers including the above-mentioned inorganic insulating material.

The first thin-film transistor TFT1 may include a semiconductor layer Act, a gate electrode GE, a drain electrode DE, and a source electrode SE. The semiconductor layer Act may include polysilicon. In some embodiments, the semiconductor layer Act may include amorphous silicon, semiconductor oxide, organic semiconductor, or the like. The semiconductor layer Act may include a channel area Act1, a drain area Act2, and a source area Act3. The drain area Act2 and the source area Act3 may be respectively arranged at opposite sides of the channel area Act1.

The gate electrode GE may overlap the channel area Act1. The gate electrode GE may include a low-resistance metal material. The gate electrode GE may include a conductive material including molybdenum (Mo), aluminum (Al), copper (Cu), titanium (Ti), or the like and may include a single layer or multiple layers including the above material.

The first gate insulating layer 113 may be arranged between the gate electrode GE and the semiconductor layer Act. The first gate insulating layer 113 may include an inorganic insulating material such as SiO₂, SiNₓ, SiON, Al₂O₃, TiO₂, Ta₂O₅, hafnium oxide (HfO₂), or ZnO.

The second gate insulating layer 115 may cover or overlap the gate electrode GE. The second gate insulating layer 115 may be arranged on the gate electrode GE and the first gate insulating layer 113. Similar to the first gate insulating layer 113, the second gate insulating layer 115 may include an inorganic insulating material such as SiO₂, SiNₓ, SiON, Al₂O₃, TiO₂, Ta₂O₅, HfO₂, or ZnO.

A second electrode Cstb of the first storage capacitor Cst1 may be arranged on the second gate insulating layer 115. The second electrode Cstb may overlap the gate electrode GE therebelow. The gate electrode GE and the second electrode Cstb overlapping each other with the second gate insulating layer 115 disposed therebetween may form the first storage capacitor Cst1. For example, the gate electrode GE may function as a first electrode Csta of the first storage capacitor Cst1.

Therefore, the first storage capacitor Cst1 and the first thin-film transistor TFT1 may overlap each other. In some embodiments, the first storage capacitor Cst1 may not overlap the first thin-film transistor TFT1. In an embodiment, the second storage capacitor Cst2 and the second thin-film transistor TFT2 may overlap each other. In some embodiments, the second storage capacitor Cst2 may not overlap the second thin-film transistor TFT2.

The second electrode Cstb may include Al, platinum (Pt), palladium (Pd), silver (Ag), magnesium (Mg), gold (Au), nickel (Ni), neodymium (Nd), iridium (Ir), chromium (Cr), calcium (Ca), Mo, Ti, tungsten (W), and/or Cu and may have a single layer or multiple layers formed of the above materials.

The interlayer insulating layer 117 may cover or overlap the second electrode Cstb. The interlayer insulating layer 117 may be arranged on the second electrode Cstb and the second gate insulating layer 115. The interlayer insulating layer 117 may include SiO₂, SiNₓ, SiON, Al₂O₃, TiO₂, Ta₂O₅, HfO₂, ZnO, or the like. The interlayer insulating layer 117 may include a single layer or multiple layers including the above-mentioned inorganic insulating materials.

The drain electrode DE and the source electrode SE may be positioned on the interlayer insulating layer 117. The drain electrode DE may be electrically connected to the drain area Act2 through a contact hole provided in the first gate insulating layer 113, the second gate insulating layer 115, and the interlayer insulating layer 117. The source electrode SE may be electrically connected to the source area Act3 through the contact hole provided in the first gate insulating layer 113, the second gate insulating layer 115, and the interlayer insulating layer 117. Each of the drain electrode DE and the source electrode SE may include a conductive material including Mo, Al, Cu, Ti, or the like and may have a single layer or multiple layers including the above material. In an embodiment, each of the drain electrode DE and the source electrode SE may have a multi-layered structure of Ti/Al/Ti.

The planarization layer 119 may cover or overlap the first thin-film transistor TFT1 and the second thin-film transistor TFT2. The planarization layer 119 may be arranged on the first thin-film transistor TFT1, the second thin-film transistor TFT2, and the interlayer insulating layer 117. The planarization layer 119 may include contact holes that expose a portion of the first thin-film transistor TFT1 and the second thin-film transistor TFT2. The planarization layer 119 may include an organic insulating layer. The planarization layer 119 may include an organic insulating material such as a general-purpose polymer (e.g., poly(methyl methacrylate) (PMMA) or polystyrene (PS)), a polymer derivative having a phenol-based group, an acryl-based polymer, an imide-based polymer, an aryl-ether-based polymer, an amide-based polymer, a fluorine-based polymer, a p-xylene-based polymer, a vinyl alcohol-based polymer, or any blends thereof.

The display element layer DEL may be arranged on the pixel circuit layer PCL. The display element layer DEL may be arranged on the planarization layer 119. The display element layer DEL may include at least one display element, a pixel-defining layer PDL, a liquid repellent pattern RP, and a capping layer 219. In an embodiment, the at least one display element may include a lower electrode 211, an emission layer 213, and an upper electrode 217. In an embodiment, the at least one display element may further include at least one of a lower functional layer 212 and an upper functional layer 215. For example, the at least one display element may further include the lower functional layer 212. In an example, the at least one display element may further include the upper functional layer 215. In an embodiment, the at least one display element may further include the lower functional layer 212 and the upper functional layer 215. Hereinafter, a case where the at least one display element includes the lower electrode 211, the lower functional layer 212, the emission layer 213, the upper functional layer 215, and the upper electrode 217 will be mainly described in detail.

The lower electrode 211 may be arranged on the pixel circuit layer PCL. In an embodiment, the lower electrode 211 may be arranged on the planarization layer 119. The lower electrode 211 may be arranged on the substrate 100. In an embodiment, the lower electrode 211 may include a first lower electrode 211A and a second lower electrode 211B that are spaced apart from each other.

The first and second lower electrodes 211A and 211B may be electrically connected to the first and second thin-film transistors TFT1 and TFT2, respectively, through contact holes provided in the planarization layer 119. For example, the first lower electrode 211A may be electrically connected to the first thin-film transistor TFT1 through a contact hole provided in the planarization layer 119. The second lower electrode 211B may be electrically connected to the second thin-film transistor TFT2 through a contact hole provided in the planarization layer 119.

In an embodiment, the lower electrode 211 may have a multi-layered structure of Ti/Al/Ti. In an embodiment, the lower electrode 211 may include a conductive oxide such as indium tin oxide (ITO), indium zinc oxide (IZO), ZnO, indium oxide (In₂O₃), indium gallium oxide (IGO), or aluminum zinc oxide (AZO). In an embodiment, the lower electrode 211 may include a reflective film including Ag, Mg, Al, Pt, Pd, Au, Ni, Nd, Ir, Cr, or compounds thereof. In an embodiment, the lower electrode 211 may further include a film including ITO, IZO, ZnO, or In₂O₃, on or below the above-described reflective film.

The pixel-defining layer PDL may cover or overlap edges of the lower electrode 211 and may include an opening OP exposing a central portion of the lower electrode 211. In an embodiment, the opening OP may include a first opening OP1 and a second opening OP2. The pixel-defining layer PDL may cover or overlap edges of the first lower electrode 211A and may include the first opening OP1 exposing a central portion of the first lower electrode 211A. The first opening OP1 may overlap the first lower electrode 211A. In an embodiment, the first opening OP1 may overlap the central portion of the first lower electrode 211A. The pixel-defining layer PDL may cover or overlap edges of the second lower electrode 211B and may include the second opening OP2 exposing a central portion of the second lower electrode 211B. The second opening OP2 may overlap the second lower electrode 211B. In an embodiment, the second opening OP2 may overlap the central portion of the second lower electrode 211B. The pixel-defining layer PDL may include an organic insulating layer and/or an inorganic insulating layer.

The opening OP may be defined by a side surface PDLSS of the pixel-defining layer PDL. In an embodiment, a portion of the side surface PDLSS of the pixel-defining layer PDL may face another part of the side surface PDLSS of the pixel-defining layer PDL. In an embodiment, the first opening OP1 may be defined by a first side surface PDLSS1 of the pixel-defining layer PDL. In an embodiment, the second opening OP2 may be defined by a second side surface PDLSS2 of the pixel-defining layer PDL.

The first opening OP1 may define a first light-emitting area EA1 of light emitted from the first organic light-emitting diode OLED1. For example, a width of the first opening OP1 may correspond to a width of the first light-emitting area EA1. The width of the first opening OP1 may be defined as a shortest distance between the first side surfaces PDLSS1 of the pixel-defining layer PDL facing each other. The width of the first opening OP1 may correspond to a width of the first subpixel PX1. The second opening OP2 may define a second light-emitting area EA2 of light emitted from the second organic light-emitting diode OLED2. For example, a width of the second opening OP2 may correspond to a width of the second light-emitting area EA2. The width of the second opening OP2 may be defined as a shortest distance between the second side surfaces PDLSS2 of the pixel-defining layer PDL facing each other. The width of the second opening OP2 may correspond to a width of the second subpixel PX2.

The emission layer 213 may be arranged on the lower electrode 211. For example, the emission layer 213 may include a first emission layer 213A and a second emission layer 213B that are spaced apart from each other. The first emission layer 213A and the second emission layer 213B may be separated from each other by the pixel-defining layer PDL. The first emission layer 213A may be arranged on the first lower electrode 211A. The second emission layer 213B may be arranged on the second lower electrode 211B.

The emission layer 213 may overlap the opening OP. In an embodiment, the emission layer 213 may be arranged inside the opening OP. For example, the first emission layer 213A may overlap the first opening OP1. The first emission layer 213A may be arranged inside the first opening OP1. The second emission layer 213B may overlap the second opening OP2. The second emission layer 213B may be arranged inside the second opening OP2.

The emission layer 213 may include a high- or low-molecular-weight inorganic material emitting light of a color. The emission layer 213 may be formed by applying ink including a light-emitting material onto the lower electrode 211. For example, the emission layer 213 may be formed by an inkjet printing process.

The lower functional layer 212 may be arranged between the lower electrode 211 and the emission layer 213. For example, the lower functional layer 212 may include a first lower functional layer 212A and a second lower functional layer 212B that are spaced apart from each other. The first lower functional layer 212A and the second lower functional layer 212B may be separated from each other by the pixel-defining layer PDL. The first lower functional layer 212A may be arranged between the first lower electrode 211A and the first emission layer 213A. The second lower functional layer 212B may be arranged between the second lower electrode 211B and the second emission layer 213B.

The lower functional layer 212 may overlap the opening OP. In an embodiment, the lower functional layer 212 may be arranged inside the opening OP. For example, the first lower functional layer 212A may overlap the first opening OP1. The first lower functional layer 212A may be arranged inside the first opening OP1. The second lower functional layer 212B may overlap the second opening OP2. The second lower functional layer 212B may be arranged inside the second opening OP2.

The first lower functional layer 212A may include a first hole transport layer (HTL) 212Aa and a first hole injection layer (HIL) 212Ab. The second lower functional layer 212B may include a second HTL 212Ba and a second HIL 212Bb.

The lower functional layer 212 may be formed by applying ink including a high-or low-molecular-organic material onto the lower electrode 211. For example, the lower functional layer 212 may be formed by an inkjet printing process.

The liquid repellent pattern RP may have liquid repellency. In the disclosure, having liquid repellency may mean that a contact angle with respect to ink including a light-emitting material or a solvent included in the ink containing the light-emitting material forming the emission layer 213 during the inkjet process is relatively large. For example, having liquid repellency means that the contact angle with respect to the ink including the light-emitting material or the solvent included in the ink containing the light-emitting material forming the emission layer 213 during the inkjet process is about 90 degrees or greater. Having lyophilic property may mean that a contact angle with respect to ink including a light-emitting material or a solvent included in the ink containing the light-emitting material forming the emission layer 213 during the inkjet process is relatively low.

The liquid repellent pattern RP may include fluorine-based components. In an embodiment, the liquid repellent pattern RP may include a fluororesin. For example, the liquid repellent pattern RP may include an organic material having an unsaturated bond, and a fluoro group. As another example, the liquid repellent pattern RP may include an organic material having an unsaturated bond, and fluorine. The fluoro group or fluorine included in the liquid repellent pattern RP may improve the liquid repellency of a surface of the liquid repellent pattern RP.

The liquid repellent pattern RP may be arranged on the pixel-defining layer PDL. In an embodiment, liquid repellent patterns RP may be provided. Each of the liquid repellent patterns RP may be arranged on the pixel-defining layer PDL. In an embodiment, the liquid repellent patterns RP may be spaced apart from each other. The liquid repellent patterns RP may be spaced apart from each other using a mask.

The liquid repellent patterns RP may be spaced apart from each other with the opening OP positioned therebetween. For example, the liquid repellent patterns RP adjacent to each other may be spaced apart from each other with the first opening OP1 positioned therebetween. The liquid repellent patterns RP adjacent to each other may be spaced apart from each other with the second opening OP2 positioned therebetween.

The liquid repellent patterns RP adjacent to each other may be spaced apart from each other with the emission layer 213 therebetween. For example, the liquid repellent patterns RP adjacent to each other may be arranged with the first emission layer 213A positioned therebetween. The liquid repellent patterns RP adjacent to each other may be arranged with the second emission layer 213B positioned therebetween.

The liquid repellent pattern RP may be arranged on an upper surface PDLUS of the pixel-defining layer PDL and a portion of the side surface PDLSS of the pixel-defining layer PDL. The upper surface PDLUS of the pixel-defining layer PDL may be a surface of the pixel-defining layer PDL that is farthest from the substrate 100 among the pixel-defining layers PDL. In an embodiment, the upper surface PDLUS of the pixel-defining layer PDL may be flat. In an embodiment, the upper surface PDLUS of the pixel-defining layer PDL may be a curved surface. The side surface PDLSS of the pixel-defining layer PDL may be electrically connected to the upper surface PDLUS of the pixel-defining layer PDL. For example, the side surface PDLSS of the pixel-defining layer PDL may meet the upper surface PDLUS of the pixel-defining layer PDL. The liquid repellent pattern RP may cover or overlap the upper surface PDLUS of the pixel-defining layer PDL. The liquid repellent pattern RP may extend from the upper surface PDLUS of the pixel-defining layer PDL to the side surface PDLSS of the pixel-defining layer PDL. For example, the liquid repellent pattern RP may extend from the upper surface PDLUS of the pixel-defining layer PDL to the first side surface PDLSS1 of the pixel-defining layer PDL. The liquid repellent pattern RP may extend from the upper surface PDLUS of the pixel-defining layer PDL to the second side surface PDLSS2 of the pixel-defining layer PDL. The liquid repellent pattern RP may extend from the upper surface PDLUS of the pixel-defining layer PDL to each of the first side surface PDLSS1 and the second side surface PDLSS2 of the pixel-defining layer PDL.

The liquid repellent pattern RP may be arranged on a portion of the side surface PDLSS of the pixel-defining layer PDL. In an embodiment, the liquid repellent pattern RP may be arranged on a portion of the first side surface PDLSS1 of the pixel- defining layer PDL. The liquid repellent pattern RP may be arranged on a portion of the second side surface PDLSS2 of the pixel-defining layer PDL.

The side surface PDLSS of the pixel-defining layer PDL may include a first surface S1 and a second surface S2. The first surface S1 may be a surface connected or extending to the upper surface PDLUS of the pixel-defining layer PDL. The second surface S2 may be a surface that extends from the first surface S1 toward the lower electrode 211. The liquid repellent pattern RP may overlap the first surface S1. The liquid repellent pattern RP may be spaced apart from the second surface S2.

The first surface S1 and the second surface S2 may be defined with respect to an edge RPE of the liquid repellent pattern RP. The edge RPE of the liquid repellent pattern RP may be a portion of the liquid repellent pattern RP that is closest to the substrate 100. The first surface S1 may be the side surface PDLSS of the pixel-defining layer PDL extending from the upper surface PDLUS of the pixel-defining layer PDL to the edge RPE of the liquid repellent pattern RP. The second surface S2 may be the side surface PDLSS of the pixel-defining layer PDL extending from the edge RPE of the liquid repellent pattern RP to the lower electrode 211. The second surface S2 may be exposed between the lower electrode 211 and the liquid repellent pattern RP.

The second surface S2 may at least partially overlap the emission layer 213. In an embodiment, the second surface S2 may overlap the lower functional layer 212 and the emission layer 213. The liquid repellent pattern RP may be arranged on the first surface S1, and the lower functional layer 212 and the emission layer 213 may be arranged on the second surface S2.

The liquid repellent pattern RP may control a thickness and/or shape of the emission layer 213 arranged on the lower electrode 211. Because the liquid repellent pattern RP may have liquid repellency, the emission layer 213 may maintain a relatively high contact angle with respect to the liquid repellent pattern RP. Because the side surface PDLSS of the pixel-defining layer PDL may have lyophilic properties, the emission layer 213 may maintain a relatively small contact angle with respect to the second surface S2. The thickness and/or shape of the emission layer 213 may vary depending on a length of the liquid repellent pattern RP arranged on the side surface PDLSS of the pixel-defining layer PDL. Therefore, the thickness of the emission layer 213 may be kept constant according to the length of the liquid repellent pattern RP arranged on the side surface PDLSS of the pixel-defining layer PDL.

In an embodiment, the liquid repellent pattern RP may adjust a position of an edge 213E of the emission layer 213. The edge 213E of the emission layer 213 may be an end of the emission layer 213 where the emission layer 213 and the pixel-defining layer PDL meet each other. For example, the position of the edge 213E of the emission layer 213 may be determined according to a position of the edge RPE of the liquid repellent pattern RP. The position of the liquid repellent pattern RP may be adjusted so that the position of the edge 213E of the emission layer 213 is positioned at any place of the side surface PDLSS of the pixel-defining layer PDL. Therefore, the position of the edge 213E of the emission layer 213 may be adjusted so that the thickness of the emission layer 213 is kept constant by using the liquid repellent pattern RP.

The liquid repellent pattern RP may be spaced apart from the lower electrode 211. In an embodiment, a first distance d1 from the substrate 100 to the edge RPE of the liquid repellent pattern RP may be greater than a second distance d2 from the substrate 100 to an upper surface 211US of the lower electrode 211. In an embodiment, a difference between the first distance d1 and the second distance d2 may be about 1000 Å to about 3000 Å. In an embodiment, a difference between the first distance d1 and the second distance d2 may be about 1000 Å to about 2000 Å. In case that the liquid repellent pattern RP extends along the side surface PDLSS of the pixel-defining layer PDL and contacts the lower electrode 211, the emission layer 213 may not be arranged on a portion of the upper surface 211US of the lower electrode 211, and thus a short circuit may occur. In an embodiment, the liquid repellent pattern RP may be spaced apart from the lower electrode 211, thereby preventing or reducing short circuits.

The upper electrode 217 may be arranged on the emission layer 213. The upper electrode 217 may be a common layer that is provided as a single body on the substrate 100. In an embodiment, the upper electrode 217 may extend from the first emission layer 213A onto the liquid repellent pattern RP. The upper electrode 217 may overlap the liquid repellent pattern RP at the upper surface PDLUS of the pixel-defining layer PDL. The upper electrode 217 may extend from the liquid repellent pattern RP to the second emission layer 213B. The upper electrode 217 may be arranged on the second emission layer 213B.

The upper electrode 217 may include a conductive material having a low work function. For example, the upper electrode 217 may include a transparent or semi-transparent layer including Ag, Mg, Al, Pt, Pd, Au, Ni, Nd, Ir, Cr, lithium (Li), Ca, or alloys thereof. As another example, the upper electrode 217 may further include a layer including, for example, ITO, IZO, ZnO, or In₂O₃, on the transparent or semi-transparent layer including the above-mentioned materials.

The upper functional layer 215 may be arranged between the emission layer 213 and the upper electrode 217. The upper functional layer 215 may be a common layer that is provided as a single body on the substrate 100. In an embodiment, the upper functional layer 215 may be arranged between the first emission layer 213A and the upper electrode 217. The upper functional layer 215 may extend from the first emission layer 213A to the liquid repellent pattern RP. The upper functional layer 215 may overlap the liquid repellent pattern RP on the upper surface PDLUS of the pixel-defining layer PDL. The upper functional layer 215 may be arranged between the liquid repellent pattern RP and the upper electrode 217 on the upper surface PDLUS of the pixel-defining layer PDL. The upper functional layer 215 may extend from the liquid repellent pattern RP to the second emission layer 213B. The upper functional layer 215 may be arranged between the second emission layer 213B and the upper electrode 217. In an embodiment, the upper functional layer 215 may include at least one of an electron transport layer (ETL) and an electron injection layer (EIL).

The capping layer 219 may be arranged on the upper electrode 217. The capping layer 219 may be a common layer that is provided as a single body on the substrate 100. In an embodiment, the capping layer 219 may extend from the first emission layer 213A to the liquid repellent pattern RP. The capping layer 219 may overlap the liquid repellent pattern RP on the upper surface PDLUS of the pixel-defining layer PDL. The capping layer 219 may extend from the liquid repellent pattern RP to the second emission layer 213B. The capping layer 219 may be arranged on the second emission layer 213B. The capping layer 219 may include lithium fluoride (LiF), an inorganic material, and/or an organic material.

Referring to FIG. 4B, a spacer SPC may be further arranged between the pixel-defining layer PDL and the liquid repellent pattern RP. The spacer SPC may be arranged on the upper surface PDLUS of the pixel-defining layer PDL. In a method of manufacturing a display device, the spacer SPC may prevent damage to the substrate 100 and/or to a multi-layered film on the substrate 100. In an embodiment, in case that the display element layer DEL is covered or overlapped by the substrate 100 and the encapsulation substrate ENS (see FIG. 3B), the encapsulation substrate ENS (see FIG. 3B) may contact the display element layer DEL, damaging the display element. In an embodiment, in case that the spacer SPC is arranged between the pixel-defining layer PDL and the liquid repellent pattern RP, damage to the display element layer DEL due to the encapsulation substrate ENS (see FIG. 3B) may be prevented or reduced. In some embodiments, a mask sheet may be used in the method of manufacturing a display device, and the mask sheet may enter the opening OP of the pixel-defining layer PDL or contact the pixel-defining layer PDL. The spacer SPC may prevent a portion of the substrate 100 or the multi-layered film from being damaged or destroyed by the mask sheet in case that a deposition material is deposited on the substrate 100.

The spacer SPC may include an organic material such as polyimide. As another example, the spacer SPC may include an inorganic insulating layer such as SiNₓ or SiOₓ, or may include an organic insulating material and an inorganic insulating material.

In an embodiment, the spacer SPC may include a material different from a material of the pixel-defining layer PDL. In an embodiment, the spacer SPC and the pixel-defining layer PDL may include a same material, and the pixel-defining layer PDL and the spacer SPC may be formed together in a mask process by using a half-tone mask or the like.

The liquid repellent pattern RP may cover or overlap the pixel-defining layer PDL and spacer SPC. In an embodiment, the liquid repellent pattern RP, the upper functional layer 215, the upper electrode 217, and the capping layer 219 may be arranged on the pixel-defining layer PDL and spacer SPC.

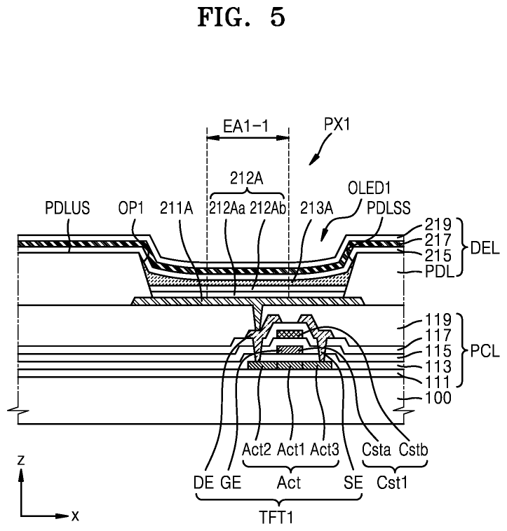

FIG. 5 is a cross-sectional view schematically illustrating a Comparative Example for comparison with an embodiment. FIG. 5 schematically illustrates a first subpixel PX1.

Referring to FIG. 5, a repellent pattern may be omitted, and a pixel-defining layer PDL may have liquid repellency. The pixel-defining layer PDL may have liquid repellency by performing a first plasma treatment on a surface of the pixel-defining layer PDL using oxygen (O₂) and/or carbon tetrafluoride (CF₄). In case that the first plasma treatment is used, a contact angle between the pixel-defining layer PDL and the first emission layer 213A may increase. However, a contact angle of the first lower functional layer 212A and/or the first emission layer 213A with respect to the first lower electrode 211A may also increase. The first lower functional layer 212A and/or the first emission layer 213A formed on the first lower electrode 211A may not have a constant thickness.

In some embodiments, a component included in the pixel-defining layer PDL may have liquid repellency. The upper surface PDLUS of the pixel-defining layer PDL may be relatively repellent, but a side surface PDLSS of the pixel-defining layer PDL may be relatively lyophilic. For example, in case that a thermal curing process is performed after the pixel-defining layer PDL having liquid repellency is formed, the side surface PDLSS of the pixel-defining layer PDL may be relatively lyophilic. The first lower functional layer 212A and/or the first emission layer 213A formed on the first lower electrode 211A may not have a constant thickness. For example, an upper surface of the first emission layer 213A may have a concave surface as shown in FIG. 5. In another example, the upper surface of the first emission layer 213A may have a convex surface. In another example, the upper surface of the first emission layer 213A may have a concave surface and a convex surface.

For various reasons, in case that the first emission layer 213A formed on the first lower electrode 211A does not have a constant thickness, a luminance of the first organic light-emitting diode OLED1 may vary depending on a thickness of the first emission layer 213A. For example, in case that the upper surface of the first emission layer 213A has a concave surface, a thickness of the first emission layer 213A overlapping an edge of the first lower electrode 211A may be greater than that of the first emission layer 213A overlapping a central portion of the first lower electrode 211A. Light may not be extracted from the first emission layer 213A that overlaps the edge of the first lower electrode 211A, and a width of a first light-emitting area EA1-1 may decrease.

In an embodiment, the liquid repellent pattern RP may be arranged on an upper surface PDLUS of the pixel-defining layer PDL and on a portion of a side surface PDLSS of the pixel-defining layer PDL. Because the liquid repellent pattern RP may have liquid repellency, the emission layer 213 may maintain a relatively high contact angle with respect to the liquid repellent pattern RP. The thickness and/or shape of the emission layer 213 may vary depending on a length of the liquid repellent pattern RP arranged on the side surface PDLSS of the pixel-defining layer PDL. Therefore, according to the length of the liquid repellent pattern RP arranged on the side surface PDLSS of the pixel-defining layer PDL, the thickness of the emission layer 213 may be kept constant, and the width of the first light-emitting area EA1 may increase.

In case that the pixel-defining layer PDL has liquid repellency as in the Comparative Example, it may be difficult to form a spacer SPC on the pixel-defining layer PDL. In an embodiment, the pixel-defining layer PDL does not need to have liquid repellency, and thus the spacer SPC may be arranged on the pixel-defining layer PDL. Therefore, in a method of manufacturing a display device, the spacer SPC may prevent damage to the substrate 100 and/or to a multi-layered film on the substrate 100.

In an embodiment, a surface of the lower electrode 211 may be cleaned by performing a second plasma treatment using O₂ and/or dinitrogen (N₂). Debris including a material identical to that of the pixel-defining layer PDL formed on the surface of the lower electrode 211 may be removed. In case that the pixel-defining layer PDL has liquid repellency as in the Comparative Example, the liquid repellency of the pixel-defining layer PDL may be reduced by the second plasma treatment. In case that the second plasma treatment is not performed, the debris may remain on the surface of the lower electrode 211, and the life of the first organic light-emitting diode OLED1 may be reduced.

In an embodiment, because the liquid repellent pattern RP is formed after the second plasma treatment, as will be described below, the liquid repellent pattern RP may maintain the liquid repellency. Therefore, the thickness of the emission layer 213 may be kept constant according to a length of the liquid repellent pattern RP arranged on the side surface PDLSS of the pixel-defining layer PDL. Because the second plasma treatment may be performed in the embodiment, debris including a material identical to that of the pixel-defining layer PDL formed on the surface of the lower electrode 211 may be removed. Therefore, the life of the first organic light-emitting diode OLED1 may increase.

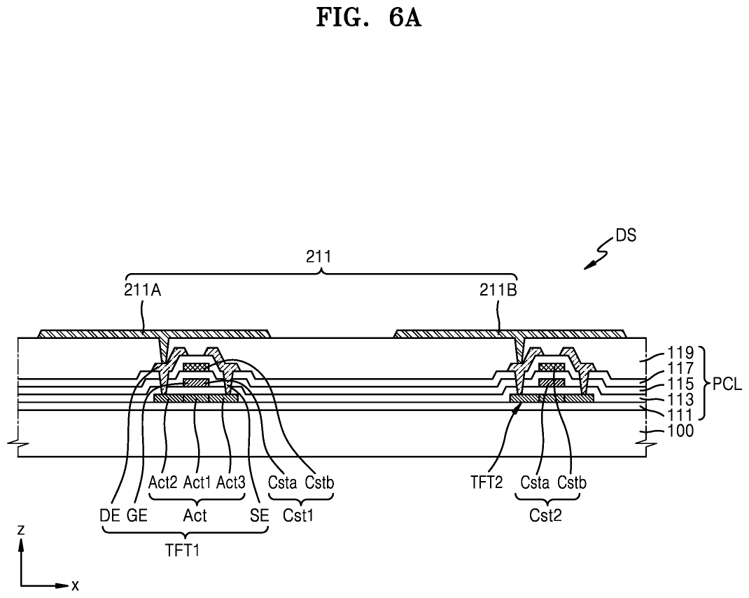

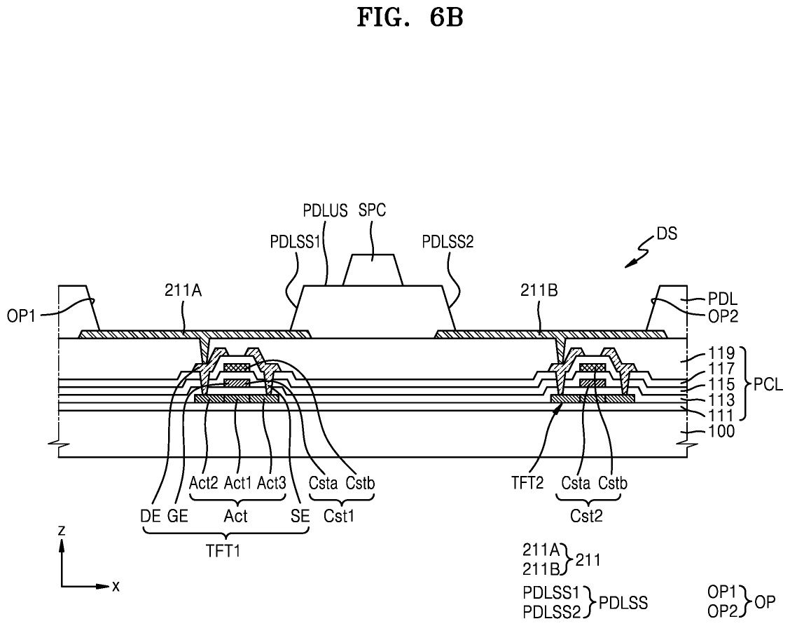

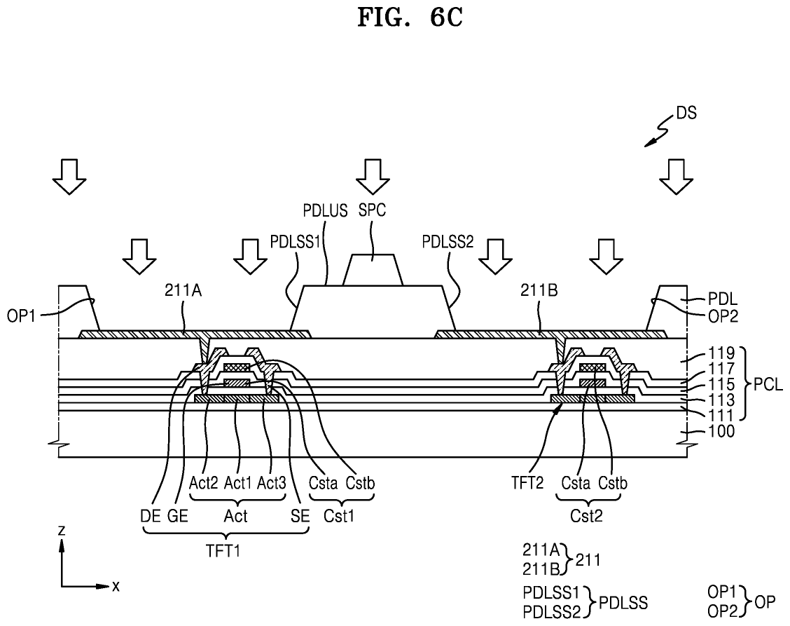

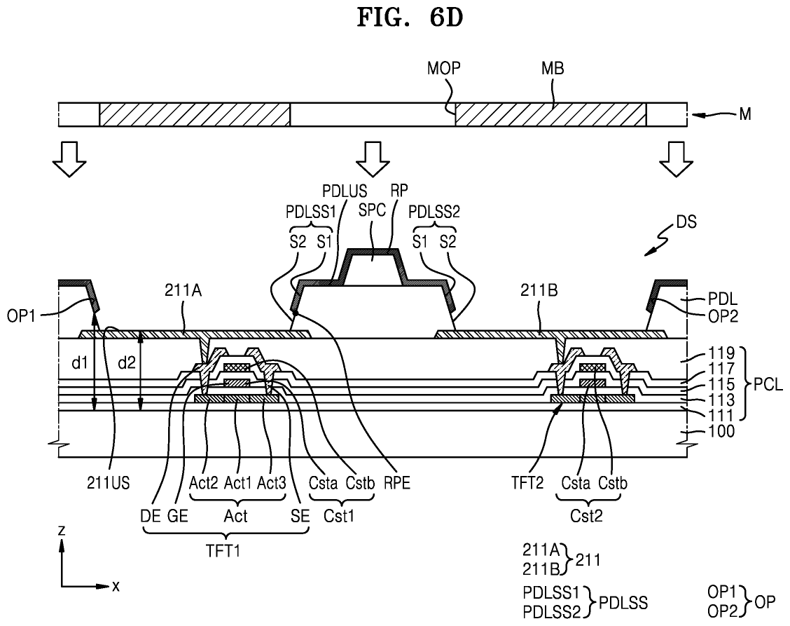

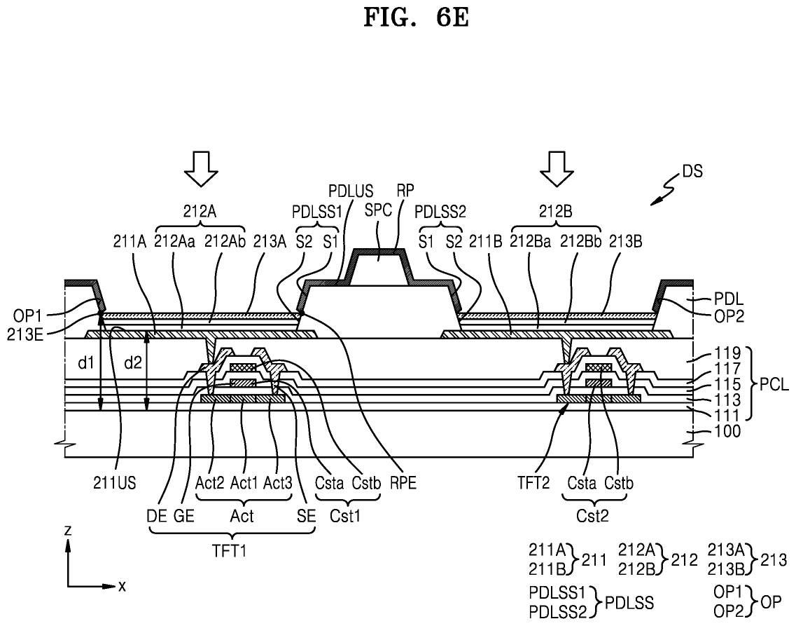

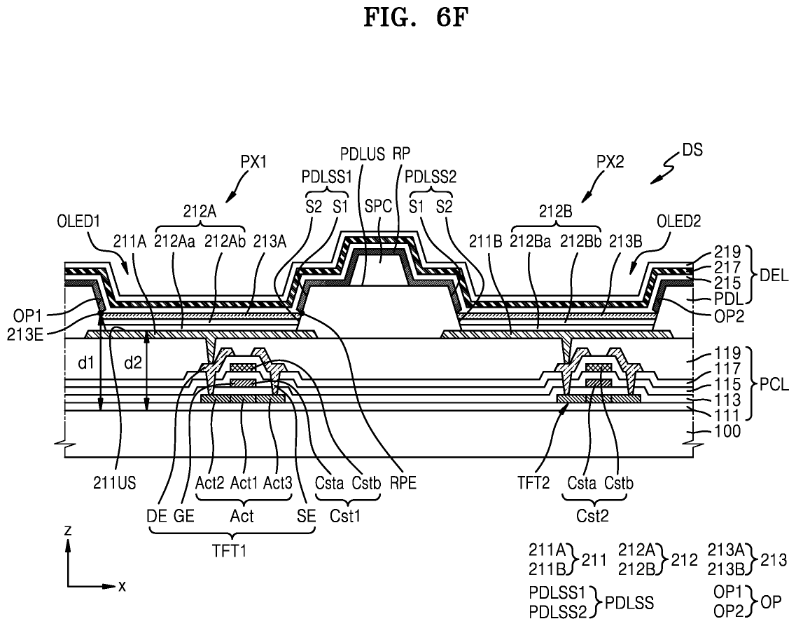

FIGS. 6A to 6F are schematic cross-sectional views illustrating a method of manufacturing a display device according to an embodiment. In FIGS. 6A to 6F, the same reference symbols as those of FIG. 4B denote the same members, and repetitive descriptions thereof will be omitted.

Referring to FIG. 6A, a display substrate DS may be prepared. The display substrate DS may be a display device that is being manufactured. The display substrate DS may include a substrate 100 and a lower electrode 211 arranged on the substrate 100. A pixel circuit layer PCL may be arranged between the substrate 100 and the lower electrode 211. The pixel circuit layer PCL may include at least one thin-film transistor, at least one storage capacitor, a buffer layer 111, a first gate insulating layer 113, a second gate insulating layer 115, an interlayer insulating layer 117, and a planarization layer 119. The at least one thin-film transistor may include a first thin-film transistor TFT1 and a second thin-film transistor TFT2. The at least one storage capacitor may include a first storage capacitor Cst1 and a second storage capacitor Cst2.

The lower electrode 211 may be arranged on the pixel circuit layer PCL. In an embodiment, the lower electrode 211 may be arranged on the planarization layer 119. In an embodiment, the lower electrode 211 may include a first lower electrode 211A and a second lower electrode 211B that are spaced apart from each other.

Referring to FIG. 6B, a pixel-defining layer PDL may be formed. The pixel-defining layer PDL may overlap edges of the lower electrode 211 and may include an opening OP that exposes a central portion of the lower electrode 211.

In an embodiment, the pixel-defining layer PDL may be entirely formed on the pixel circuit layer PCL. The pixel-defining layer PDL may be formed by various methods such as spin coating, slit coating, spraying, immersing, or the like.

Thereafter, at least a portion of the pixel-defining layer PDL may be exposed, and the at least a portion of the pixel-defining layer PDL may be removed by a development process. Therefore, the opening OP exposing the central portion of the lower electrode 211 may be formed.

In an embodiment, the opening OP may include a first opening OP1 and a second opening OP2. For example, the pixel-defining layer PDL may cover or overlap edges of a first lower electrode 211A and may include a first opening OP1 that exposes a central portion of the first lower electrode 211A. The first opening OP1 may overlap the first lower electrode 211A. In an embodiment, the first opening OP1 may overlap the central portion of the first lower electrode 211A. The pixel-defining layer PDL may cover or overlap edges of a second lower electrode 211B and may include a second opening OP2 that exposes a central portion of the second lower electrode 211B. The second opening OP2 may overlap the second lower electrode 211B. In an embodiment, the second opening OP2 may overlap the central portion of the second lower electrode 211B.

The opening OP may be defined by a side surface PDLSS of the pixel-defining layer PDL. In an embodiment, the first opening OP1 may be defined by a first side surface PDLSS1 of the pixel-defining layer PDL. In an embodiment, the second opening OP2 may be defined by a second side surface PDLSS2 of the pixel-defining layer PDL.

A spacer SPC may be formed on the pixel-defining layer PDL. The spacer SPC may be formed on an upper surface PDLUS of the pixel-defining layer PDL. In an embodiment, the spacer SPC and the pixel-defining layer PDL may be formed by a same process. The pixel-defining layer PDL and the spacer SPC may be formed together in a mask process by using a half-tone mask or the like. The spacer SPC and the pixel-defining layer PDL may include a same material. In an embodiment, the spacer SPC may be formed by a process different from a process by which the pixel-defining layer PDL is formed.

In case that the pixel-defining layer PDL has liquid repellency as in the Comparative Example, it may be difficult to form the spacer SPC on the pixel-defining layer PDL. In an embodiment, the pixel-defining layer PDL does not need to have liquid repellency, and thus the spacer SPC may be arranged on the pixel-defining layer PDL. Therefore, in a method of manufacturing a display device, the damage to the substrate 100 and/or to a multi-layered film on the substrate 100 may be prevented. In some embodiments, the spacer SPC may be omitted.

Referring to FIG. 6C, the display substrate DS may be plasma-cleaned. A surface of the lower electrode 211 of the display substrate DS may be cleaned with O₂ and/or N₂. In an embodiment, in case that the opening OP is formed after the pixel-defining layer PDL is entirely formed on the display substrate DS, debris including a material identical to that of the pixel-defining layer PDL may remain on the surface of the lower electrode 211. In case that the debris remains, an emission layer may be formed on the upper surface of the lower electrode 211 to have a non-uniform thickness and may affect the luminance of the manufactured display element. The life of the manufactured display element may decrease.

When the surface of the lower electrode 211 is cleaned with O₂ and/or N₂ as in the embodiment, the debris may be removed. Therefore, the emission layer may be formed on the upper surface of the lower electrode 211 to have a constant thickness, and the life of the manufactured display element may increase.

Referring to FIG. 6D, a liquid repellent pattern RP may be formed. The liquid repellent pattern RP may be formed on an upper surface PDLUS of the pixel-defining layer PDL and a portion of the side surface PDLSS of the pixel-defining layer PDL. In an embodiment, the liquid repellent pattern RP may cover or overlap the pixel-defining layer PDL and the spacer SPC. Liquid repellent patterns RP may be formed, and the liquid repellent patterns RP may be spaced apart from each other.

The liquid repellent patterns RP may be spaced apart from each other with the opening OP positioned therebetween. For example, the liquid repellent patterns RP adjacent to each other may be spaced apart from each other with the first opening OP1 therebetween. The liquid repellent patterns RP adjacent to each other may be spaced apart from each other with the second opening OP2 therebetween.

The liquid repellent pattern RP may be formed on an upper surface PDLUS of the pixel-defining layer PDL and a portion of the side surface PDLSS of the pixel-defining layer PDL. The liquid repellent pattern RP may cover or overlap the upper surface PDLUS of the pixel-defining layer PDL. The liquid repellent pattern RP may extend from the upper surface PDLUS of the pixel-defining layer PDL to the side surface PDLSS of the pixel-defining layer PDL. For example, the liquid repellent pattern RP may extend from the upper surface PDLUS of the pixel-defining layer PDL to the first side surface PDLSS1 of the pixel-defining layer PDL. The liquid repellent pattern RP may extend from the upper surface PDLUS of the pixel-defining layer PDL to the second side surface PDLSS2 of the pixel-defining layer PDL. The liquid repellent pattern RP may extend from the upper surface PDLUS of the pixel-defining layer PDL to each of the first side surface PDLSS1 of the pixel-defining layer PDL and the second side surface PDLSS2 of the pixel-defining layer PDL.

The liquid repellent pattern RP may be arranged on a portion of the side surface PDLSS of the pixel-defining layer PDL. In an embodiment, the liquid repellent pattern RP may be arranged on a portion of the first side surface PDLSS1 of the pixel-defining layer PDL. The liquid repellent pattern RP may be arranged on a portion of the second side surface PDLSS2 of the pixel-defining layer PDL.

The side surface PDLSS of the pixel-defining layer PDL may include a first surface S1 and a second surface S2. The first surface S1 may be a surface that is connected or extending to the upper surface PDLUS of the pixel-defining layer PDL. The second surface S2 may be a surface that extends from the first surface S1 toward the lower electrode 211. The liquid repellent pattern RP may overlap the first surface S1. The liquid repellent pattern RP may be spaced apart from the second surface S2.

The first surface S1 and the second surface S2 may be defined with respect to the edge RPE of the liquid repellent pattern RP. The first surface S1 may be the side surface PDLSS of the pixel-defining layer PDL that extends from the upper surface PDLUS of the pixel-defining layer PDL to an edge RPE of the liquid repellent pattern RP. The second surface S2 may be the side surface PDLSS of the pixel-defining layer PDL that extends from the edge RPE of the liquid repellent pattern RP to the lower electrode 211. The second surface S2 may be exposed between the lower electrode 211 and the liquid repellent pattern RP.

The liquid repellent pattern RP may be spaced apart from the lower electrode 211. In an embodiment, a first distance d1 from the substrate 100 to the edge RPE of the liquid repellent pattern RP may be greater than a second distance d2 from the substrate 100 to an upper surface 211US of the lower electrode 211. In an embodiment, a difference between the first distance d1 and the second distance d2 may be about 1000 Å to about 3000 Å. In an embodiment, a difference between the first distance d1 and the second distance d2 may be about 1000 Å to about 2000 Å. In case that the liquid repellent pattern RP extends along the side surface PDLSS of the pixel-defining layer PDL and contacts the lower electrode 211, the emission layer 213 may not be arranged on a portion of the upper surface 211US of the lower electrode 211, and thus a short circuit may occur. In an embodiment, the liquid repellent pattern RP may be spaced apart from the lower electrode 211, thereby preventing or reducing short circuits.

The liquid repellent pattern RP may include fluorine-based components. In an embodiment, the liquid repellent pattern RP may include a fluororesin. For example, the liquid repellent pattern RP may include an organic material having an unsaturated bond, and a fluoro group. In some embodiments, the liquid repellent pattern RP may include an organic material having an unsaturated bond, and fluorine. The fluoro group or fluorine included in the liquid repellent pattern RP may improve the liquid repellency of a surface of the liquid repellent pattern RP.

In an embodiment, a mask M having a mask opening MOP may be arranged on the display substrate DS. The mask M may include a mask body MB and the mask opening MOP. Mask openings MOP may be provided in the mask M. The mask opening MOP may be arranged to overlap the pixel-defining layer PDL. The mask body MB may be arranged to overlap the opening OP.

Thereafter, the liquid repellent pattern RP may be deposited. Therefore, the liquid repellent pattern RP may be formed to overlap the pixel-defining layer PDL. In an embodiment, after the mask M including the mask opening MOP is disposed on the display substrate DS, the liquid repellent pattern RP may be deposited. Therefore, the liquid repellent patterns RP spaced apart from each other may be formed on the pixel-defining layer PDL. A process of forming the liquid repellent pattern RP after placing the mask M on the display substrate DS may precisely control a position where the liquid repellent pattern RP is formed and a size of the liquid repellent pattern RP. For example, a size of the first surface S1 on which the liquid repellent pattern RP is formed and a size of the second surface S2 extending from the edge RPE of the liquid repellent pattern RP to the lower electrode 211 may be adjusted. In an embodiment, by using the mask M, the liquid repellent pattern RP may be formed with a process error of about 1 μm or less.

In an embodiment, the liquid repellent pattern RP may be formed after the display substrate DS is plasma-cleaned. In case that the pixel-defining layer PDL has liquid repellency unlike an embodiment, cleaning of the surface of the lower electrode 211 by a second plasma treatment with O₂ and/or N₂ may reduce the liquid repellency of the pixel-defining layer PDL. As will be described below, in case that the emission layer 213 is formed by applying ink including a light-emitting material, the emission layer 213 may be formed on the upper surface PDLUS of the pixel-defining layer PDL. In an embodiment, because the liquid repellent pattern RP is formed after the display substrate DS is plasma-cleaned, the liquid repellency of the liquid repellent pattern RP may be maintained.

Referring to FIG. 6E, a lower functional layer 212 may be formed on the lower electrode 211. The lower functional layer 212 may overlap the opening OP. The lower functional layer 212 may include a first lower functional layer 212A and a second lower functional layer 212B that are spaced apart from each other. The first lower functional layer 212A and the second lower functional layer 212B may be separated from each other by the pixel-defining layer PDL.

The lower functional layer 212 may be formed inside the opening OP. For example, the first lower functional layer 212A may overlap the first opening OP1. The first lower functional layer 212A may be formed inside the first opening OP1. The second lower functional layer 212B may overlap the second opening OP2. The second lower functional layer 212B may be formed inside the second opening OP2.

The first lower functional layer 212A may include a first HTL 212Aa and a first HIL 212Ab. The second lower functional layer 212B may include a second HTL 212Ba and a second HIL 212Bb.

The lower functional layer 212 may be formed by applying ink including a high-or low-molecular-organic material onto the lower electrode 211. For example, the lower functional layer 212 may be formed by an inkjet printing process. An accurate alignment between an inkjet discharge port (not shown) and the opening OP may be required. In case that the inkjet discharge port and the opening OP are not accurately aligned with each other, the lower functional layer 212 may be formed on the upper surface PDLUS of the pixel-defining layer PDL. In the embodiment, because the liquid repellent pattern RP arranged in a portion among the upper surface PDLUS of the pixel-defining layer PDL and the side surface PDLSS of the pixel-defining layer PDL has liquid repellency, the lower functional layer 212 may not be formed on the upper surface PDLUS of the pixel-defining layer PDL. Therefore, the first lower functional layer 212A and the second lower functional layer 212B may be formed in the first opening OP1 and the second opening OP2, respectively.

The emission layer 213 may be formed on the lower electrode 211. In case that the lower functional layer 212 is formed on the lower electrode 211, the emission layer 213 may be formed on the lower functional layer 212. For example, the emission layer 213 may include a first emission layer 213A and a second emission layer 213B that are spaced apart from each other. The first emission layer 213A and the second emission layer 213B may be separated from each other by the pixel-defining layer PDL. The first emission layer 213A may be formed on the first lower electrode 211A. The second emission layer 213B may be formed on the second lower electrode 211B.

The emission layer 213 may overlap the opening OP. In an embodiment, the emission layer 213 may be formed inside the opening OP. For example, the first emission layer 213A may overlap the first opening OP1. The first emission layer 213A may be arranged inside the first opening OP1. The second emission layer 213B may overlap the second opening OP2. The second emission layer 213B may be formed inside the second opening OP2.

The emission layer 213 may be formed by applying ink including a light-emitting material to the lower electrode 211 and/or the lower functional layer 212. For example, the emission layer 213 may be formed by an inkjet printing process. An accurate alignment between the inkjet discharge port (not shown) and the opening OP may be required. In case that the inkjet discharge port and the opening OP are not accurately aligned with each other, the emission layer 213 may be formed on the upper surface PDLUS of the pixel-defining layer PDL. In the embodiment, because the liquid repellent pattern RP arranged in a portion among the upper surface PDLUS of the pixel-defining layer PDL and the side surface PDLSS of the pixel-defining layer PDL has liquid repellency, the emission layer 213 may not be formed on the upper surface PDLUS of the pixel-defining layer PDL. Therefore, the first emission layer 213A and the second emission layer 213B may be formed in the first opening OP1 and the second opening OP2, respectively.

The second surface S2 may at least partially overlap the emission layer 213. In an embodiment, the second surface S2 may overlap the lower functional layer 212 and the emission layer 213. The liquid repellent pattern RP may be arranged on the first surface S1, and the lower functional layer 212 and the emission layer 213 may be arranged on the second surface S2.

The liquid repellent pattern RP may control or adjust a thickness and/or shape of the emission layer 213 arranged on the lower electrode 211. Because the liquid repellent pattern RP may have liquid repellency, the emission layer 213 may maintain a relatively high contact angle with respect to the liquid repellent pattern RP. Because the side surface PDLSS of the pixel-defining layer PDL may have lyophilic properties, the emission layer 213 may maintain a relatively small contact angle with respect to the second surface S2. The thickness and/or shape of the emission layer 213 may vary according to a length of the liquid repellent pattern RP arranged on the side surface PDLSS of the pixel-defining layer PDL. Therefore, the thickness of the emission layer 213 may be kept constant according to the length of the liquid repellent pattern RP arranged on the side surface PDLSS of the pixel-defining layer PDL.

In an embodiment, the liquid repellent pattern RP may adjust a position of an edge 213E of the emission layer 213. The edge 213E of the emission layer 213 may be an end of the emission layer 213 where the emission layer 213 and the pixel-defining layer PDL meet each other. For example, the position of the edge 213E of the emission layer 213 may be determined according to a position of the edge RPE of the liquid repellent pattern RP. The liquid repellent pattern RP may be adjusted so that the edge 213E of the emission layer 213 is positioned at a point of the side surface PDLSS of the pixel-defining layer PDL. Therefore, the position of the edge 213E of the emission layer 213 may be adjusted so that the thickness of the emission layer 213 is kept constant by using the liquid repellent pattern RP.

Referring to FIG. 6F, an upper functional layer 215 may be formed on the emission layer 213. The upper functional layer 215 may be formed as a single body on the substrate 100. In an embodiment, the upper functional layer 215 may extend from the first emission layer 213A to the liquid repellent pattern RP. The upper functional layer 215 may be formed on the liquid repellent pattern RP formed on the upper surface PDLUS of the pixel-defining layer PDL. The upper functional layer 215 may extend from the liquid repellent pattern RP to the second emission layer 213B. The upper functional layer 215 may be formed on the second emission layer 213B. In an embodiment, the upper functional layer 215 may include at least one of an ETL and an EIL.

The upper electrode 217 may be formed on the upper functional layer 215. The upper electrode 217 may be formed as a single body on the substrate 100. In an embodiment, the upper electrode 217 may extend from the first emission layer 213A to the liquid repellent pattern RP. The upper electrode 217 may overlap the liquid repellent pattern RP formed on the upper surface PDLUS of the pixel-defining layer PDL. The upper electrode 217 may extend from the liquid repellent pattern RP to the second emission layer 213B. The upper electrode 217 may be arranged on the second emission layer 213B.

A capping layer 219 may be formed on the upper electrode 217. The capping layer 219 may be formed as a single body on the substrate 100. In an embodiment, the capping layer 219 may extend from the first emission layer 213A to the liquid repellent pattern RP. The capping layer 219 may overlap the liquid repellent pattern RP formed on the upper surface PDLUS of the pixel-defining layer PDL. The capping layer 219 may extend from the liquid repellent pattern RP to the second emission layer 213B. The capping layer 219 may be arranged on the second emission layer 213B.

As described above, a display device according to an embodiment may include a repellent pattern that is arranged on an upper surface of a pixel-defining layer and a portion of a side surface of the pixel-defining layer, and the side surface of the pixel-defining layer may define an opening. Therefore, a shape of an emission layer may be adjusted.

In addition, a method of manufacturing a display device according to an embodiment may include forming a repellent pattern on an upper surface of a pixel-defining layer and on a portion of a side surface of the pixel-defining layer, and the side surface of the pixel-defining layer may define an opening. Therefore, a shape of an emission layer may be adjusted.

It should be understood that the embodiments described herein should be considered in a descriptive sense only and not for purposes of limitation. Descriptions of features or aspects within each of the embodiments should typically be considered as available for other similar features or aspects in other embodiments. While one or more embodiments have been described with reference to the figures, it will be understood by one of ordinary skill in the art that various changes in form and details may be made therein without departing from the spirit and scope of the disclosure including the following claims.

What is claimed is:

1. A display device comprising:
a lower electrode disposed on a substrate;
a pixel-defining layer overlapping an edge of the lower electrode, the pixel-defining layer comprising an opening that exposes a central portion of the lower electrode;
an emission layer overlapping the opening and arranged on the lower electrode;
an upper electrode disposed on the emission layer; and
at least one repellent pattern disposed on an upper surface of the pixel-defining layer and a portion of a side surface of the pixel-defining layer,
wherein the side surface of the pixel-defining layer defines the opening.

2. The display device of claim 1, wherein the side surface of the pixel-defining layer comprises:
a first surface that overlaps the at least one repellent pattern; and
a second surface that extends from an edge of the at least one repellent pattern to the lower electrode and at least partially overlaps the emission layer.

3. The display device of claim 1, wherein the at least one repellent pattern is spaced apart from the lower electrode.

4. The display device of claim 1, wherein the upper electrode overlaps the at least one repellent pattern disposed on the upper surface of the pixel-defining layer.

5. The display device of claim 1, wherein
the lower electrode comprises a first lower electrode and a second lower electrode that are spaced apart from each other,
the opening comprises a first opening and a second opening, the first opening exposing a central portion of the first lower electrode, and the second opening exposing a central portion of the second lower electrode,
the emission layer comprises a first emission layer and a second emission layer, the first emission layer being arranged on the first lower electrode, and the second emission layer being spaced apart from the first emission layer and arranged on the second lower electrode, and
the at least one repellent pattern is arranged on the upper surface of the pixel-defining layer, a portion of a first side surface of the pixel-defining layer defining the first opening, and a portion of a second side surface of the pixel-defining layer defining the second opening.

6. The display device of claim 5, further comprising:
a lower functional layer comprising a first lower functional layer and a second lower functional layer; and
an upper functional layer between the emission layer and the upper electrode, wherein
the first lower functional layer is arranged between the first lower electrode and the first emission layer,
the second lower functional layer is arranged between the second lower electrode and the second emission layer and spaced apart from the first lower functional layer, and
the upper functional layer is arranged between the at least one repellent pattern and the upper electrode on the upper surface of the pixel-defining layer.

7. The display device of claim 1, wherein
the at least one repellent pattern comprises a plurality of repellent patterns, and
the plurality of repellent patterns are spaced apart from each other with the emission layer arranged therebetween.

8. The display device of claim 1, wherein the at least one repellent pattern includes a fluorine-based component.

9. The display device of claim 1, further comprising a spacer between the pixel-defining layer and the at least one repellent pattern.

10. The display device of claim 1, further comprising a capping layer arranged on the upper electrode and overlapping the emission layer and the at least one repellent pattern.

11. A method of manufacturing a display device, the method comprising:
preparing a display substrate that comprises a substrate and a lower electrode disposed on the substrate;
forming a pixel-defining layer that overlaps an edge of the lower electrode, the pixel-defining layer comprising an opening that exposes a central portion of the lower electrode;
forming at least one repellent pattern on an upper surface of the pixel-defining layer and a portion of a side surface of the pixel-defining layer; and
forming an emission layer on the lower electrode, wherein
the side surface of the pixel-defining layer defines the opening and comprises a first surface and a second surface,
the first surface overlaps the at least one repellent pattern, and
the second surface extends from an edge of the at least one repellent pattern to the lower electrode.

12. The method of claim 11, wherein
the forming of the at least one repellent pattern comprises disposing, on the display substrate, a mask including a mask opening, and
the mask opening is arranged to overlap the pixel-defining layer.

13. The method of claim 11, wherein the at least one repellent pattern is spaced apart from the lower electrode.

14. The method of claim 11, wherein
the at least one repellent pattern comprises a plurality of repellent patterns, and
the plurality of repellent patterns are spaced apart from each other.

15. The method of claim 11, wherein the forming of the emission layer comprises applying ink including a light-emitting material onto the lower electrode.

16. The method of claim 11, further comprising:
forming an upper functional layer on the emission layer and the at least one repellent pattern; and
forming an upper electrode on the upper functional layer.

17. The method of claim 16, further comprising forming a capping layer on the upper electrode.

18. The method of claim 11, further comprising forming a lower functional layer by applying ink onto the lower electrode,
wherein the forming of the emission layer comprises forming the emission layer on the lower functional layer.

19. The method of claim 11, further comprising forming a spacer on the pixel-defining layer.

20. The method of claim 11, further comprising plasma-cleaning the lower electrode.
